(19) United States
(12) Patent Application Publication
(10) Pub. No.: US 2025/0151636 A1
(43) Pub. Date: May 8, 2025

(54) MANAGING PHASE CHANGE MATERIALS FOR MEMORY DEVICES

(71) Applicant: Macronix International Co., Ltd., Hsinchu (TW)

(72) Inventors: Huai-Yu Cheng, Hsinchu (TW); Alexander R. Grun, Mt. Kisco, NY (US)

(73) Assignee: Macronix International Co., Ltd., Hsinchu (TW)

(21) Appl. No.: 18/500,806

(22) Filed: Nov. 2, 2023

(51) Int. Cl. H10N 70/00; C22C 30/00; H10B 63/10; H10N 70/20

(52) U.S. Cl. CPC H10N 70/8828; C22C 30/00; H10B 63/10; H10N 70/231

(57) ABSTRACT

Methods, devices, apparatus, and systems for managing phase change materials for memory devices are provided. In one aspect, an integrated circuit (e.g., a memory element) includes: a first electrode, a second electrode, and a body of a phase change material coupled between the first electrode and the second electrode. The phase change material includes SiₓSb_{y}Te_{z}, where x, y, z represent respective atomic ratios for compositions Si, Sb, Te. A bulk stoichiometry of the body of the phase change material includes a Si atomic concentration within a range from about 7% to about 12%.

### TECHNICAL FIELD

The present disclosure is directed to phase change materials, e.g., those suitable for use in memory devices.

### BACKGROUND

Phase change materials, such as chalcogenide-based materials and similar materials, can be caused to change between an amorphous phase and a crystalline phase by application of electrical current at levels suitable for implementation in integrated circuits. The generally amorphous phase is characterized by higher electrical resistivity than the generally crystalline phase, which can be readily sensed to indicate data. These properties have generated interest in using programmable resistive material to form non-volatile memory circuits, which can be read and written with random access.

### SUMMARY

The present disclosure describes methods, circuits, devices, systems and techniques for managing phase change materials for memory devices, e.g., to be applied in analog artificial intelligence (AI) systems.

One aspect of the present disclosure features an integrated circuit, including: a first electrode; a second electrode; and a body of a phase change material coupled between the first electrode and the second electrode. The phase change material includes SiₓSb_{y}Te_{z}, where x, y, z represent respective atomic ratios for compositions Si, Sb, Te, and a bulk stoichiometry of the body of the phase change material includes a Si atomic concentration within a range from about 7% to about 12%.

In some embodiments, the bulk stoichiometry of the body of the phase change material includes: a Sb atomic concentration within a range from about 27% to about 42%, and a Te atomic concentration within a range from about 40% to about 60%.

In some embodiments, the phase change material includes SiC doped in SiₓSb_{y}Te_{z}.

In some embodiments, the bulk stoichiometry of the body of the phase change material includes: a C atomic concentration within a range from about 10% to about 16%.

In some embodiments, the body of the phase change material has a thickness in a range from 30 nm to 80 nm.

In some embodiments, a reset drift coefficient of the integrated circuit at a room temperature is no more than 0.04.

In some embodiments, a reset drift coefficient of the integrated circuit at an elevated temperature is no more than 0.04.

In some embodiments, a change of a conductance of the integrated circuit at an elevated temperature is no more than 10% over 1 hour.

In some embodiments, a change of a conductance of the integrated circuit at an elevated temperature is no more than 10% over 1 day.

In some embodiments, the body of the phase change material is programmable to a plurality of resistance states including a full reset state and a full set state, and a change of a conductance of each of the plurality of resistance states is no more than 10% over 1 day.

In some embodiments, the phase change material has a crystallization temperature greater than 200° C.

In some embodiments, the body of a phase change material is configured to be applied with a set pulse having a duration of no more than 200 ns to change the phase change material from an amorphous phase to a crystalline phase.

In some embodiments, the integrated circuit is configured to be a memory element with a mushroom type structure.

In some embodiments, a phase change memory device includes a plurality of memory cells. At least one of the plurality of memory cells includes the integrated circuit as described above. The phase change memory device is configured to perform an inference mode of an analog artificial intelligence (AI) model, and where, in the inference mode, memory elements of the plurality of memory cells are programmed to have a plurality of resistance states corresponding to respective weights of the plurality of memory cells, the plurality of resistance states corresponding to non-overlapping ranges of resistance values.

Another aspect of the present disclosure features an integrated circuit, including: a first electrode; a second electrode; and a body of a phase change material coupled between the first electrode and the second electrode. The phase change material includes SiₓSb_{y}Te_{z} doped with SiC, where x, y, z represent respective atomic ratios for compositions Si, Sb, Te.

In some embodiments, a bulk stoichiometry of the body of the phase change material includes: a Si atomic concentration within a range from about 7% to about 12%, a Sb atomic concentration within a range from about 27% to about 42%, a Te atomic concentration within a range from about 40% to about 60%, and a C atomic concentration within a range from about 10% to about 16%.

In some embodiments, a reset drift coefficient of the integrated circuit at an elevated temperature is no more than 0.04.

In some embodiments, the body of the phase change material is programmable to a plurality of resistance states including a full reset state and a full set state, and a change of a conductance of each of the plurality of resistance states is no more than 10% over 1 day.

In some embodiments, a phase change memory device includes a plurality of memory cells, where at least one of the plurality of memory cells includes the integrated circuit as described above. The phase change memory device is configured to perform an inference mode of an analog artificial intelligence (AI) model, and, in the inference mode, memory elements of the plurality of memory cells are programmed to have a plurality of resistance states corresponding to respective weights of the plurality of memory cells, the plurality of resistance states corresponding to non-overlapping ranges of resistance values.

Another aspect of the present disclosure a phase change memory device, including: a plurality of memory cells. Each of the plurality of memory cells includes a memory element including: a first electrode and a second electrode and a body of a phase change material coupled between the first electrode and the second electrode, where the phase change material includes SiₓSb_{y}Te_{z}, where x, y, z represent respective atomic ratios for compositions Si, Sb, Te, and where a bulk stoichiometry of the body of the phase change material includes a Si atomic concentration within a range from about 7% to about 12%, a Sb atomic concentration within a range from about 27% to about 42%, and a Te atomic concentration within a range from about 40% to about 60%; and control circuitry coupled to the plurality of memory cells and configured to control one or more operations on the plurality of memory cells.

In some embodiments, the phase change material includes SiC doped in SiₓSb_{y}Te_{z}, and the bulk stoichiometry of the body of the phase change material includes: a C atomic concentration within a range from about 10% to about 16%.

In some embodiments, the phase change memory device is configured to perform an inference mode of an analog artificial intelligence (AI) model, and where, in the inference mode, memory elements of the plurality of memory cells are programmed to have a plurality of resistance states corresponding to respective weights of the plurality of memory cells, the plurality of resistance states corresponding to non-overlapping ranges of resistance values.

The details of one or more disclosed implementations are set forth in the accompanying drawings and the description below. Other features, aspects, and advantages will become apparent from the description, the drawings and the claims.

### BRIEF DESCRIPTION OF THE DRAWINGS

FIG. 1 illustrates example operations of a memory element including a phase change material (PCM).

FIG. 2 illustrates example phase change materials with corresponding compositions (Si, Sb, Te) and reset drift coefficients (e.g., at room temperature).

FIGS. 3-4 illustrate example performance characteristics of a PCM cell fabricated from an example SiSbTe PCM (Material A).

FIGS. 5-6 illustrate example performance characteristics of a PCM cell fabricated from another example SiSbTe PCM (Material B).

FIG. 7 illustrates drift performance characteristics (at 65° C.) of PCM cells fabricated from Material A programmed at a series of resistance states over 1 hour.

FIG. 8 illustrates drift performance characteristics (at 65° C.) of PCM cells fabricated from Material B programmed at a series of resistance states over 1 hour.

FIG. 9 illustrates drift performance characteristics (at 65° C.) of PCM cells fabricated from Material B programmed at a series of resistance states over 1 day.

FIG. 10A illustrates example phase change materials with corresponding compositions (Si, Sb, Te, C) at various atomic concentrations.

FIG. 10B illustrates resistivity of Material A, Material C, Material D of FIG. 10A with as a function of temperature.

FIG. 11 illustrates example performance characteristics of a PCM cell fabricated from an example SiSbTe with low SiC doping (Material C).

FIG. 12 illustrates example performance characteristics of a PCM cell fabricated from an example SiSbTe with high SiC doping (Material D).

FIG. 13 illustrates drift performance characteristics (at 65° C.) of PCM cells fabricated from Material C programmed at a series of resistance states.

FIG. 14 illustrates drift performance characteristics (at 65° C.) of PCM cells fabricated from Material D programmed at a series of resistance states.

FIG. 15 illustrates drift performance characteristics (at 65° C.) of PCM cells fabricated from Material C programmed at a series of states over 1 day.

FIG. 16A illustrates a cross-sectional view of an example memory element made from a PCM material with a mushroom-type structure.

FIG. 16B illustrates across-sectional view of an example memory element made from a PCM material with an “active in via” type structure.

FIG. 16C illustrates a cross-sectional view of an example memory element made from a PCM material with a pore type structure.

FIG. 16D illustrates a cross-sectional view of example memory structure including multiple memory elements made from a PCM material with a cross-point structure.

FIG. 17A illustrates an integrated circuit including an array of phase change memory cells.

FIG. 17B illustrates an example of operating a portion of phase change memory cells in the phase change memory array of FIG. 17A.

FIGS. 18A and 18B illustrate an example of an artificial neural network (ANN) and an exploded view of a neuron N6 of the ANN, respectively.

FIG. 19 shows an example memory for performing a multiply-accumulate calculation (MAC).

FIG. 20A illustrates an example system for executing a training mode.

FIG. 20B illustrates an example system for executing an inference mode.

Like reference numbers and designations in the various drawings indicate like elements. It is also to be understood that the various exemplary implementations shown in the figures are merely illustrative representations and are not necessarily drawn to scale.

### DETAILED DESCRIPTION

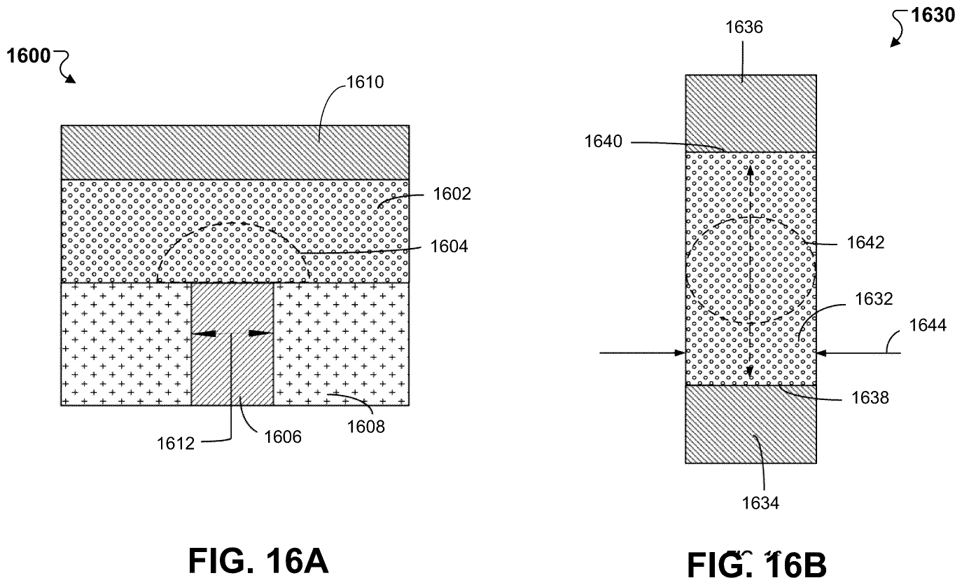

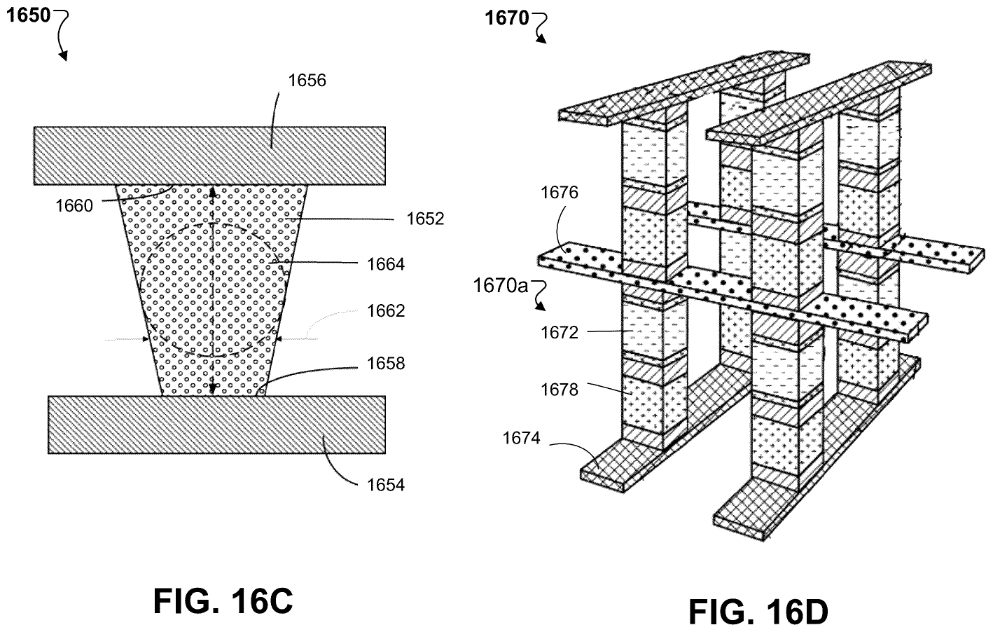

A phase change material (PCM) can be used to form a memory element, e.g., as described with further details in FIGS. 16A-16D. The memory element can include a PCM layer and first and second electrodes that are in electrical contact with the PCM layer. In operation, voltages are applied to the first and second electrodes to cause a current to pass through the PCM layer. Such current allows for the read/sense and write operation of the memory cell.

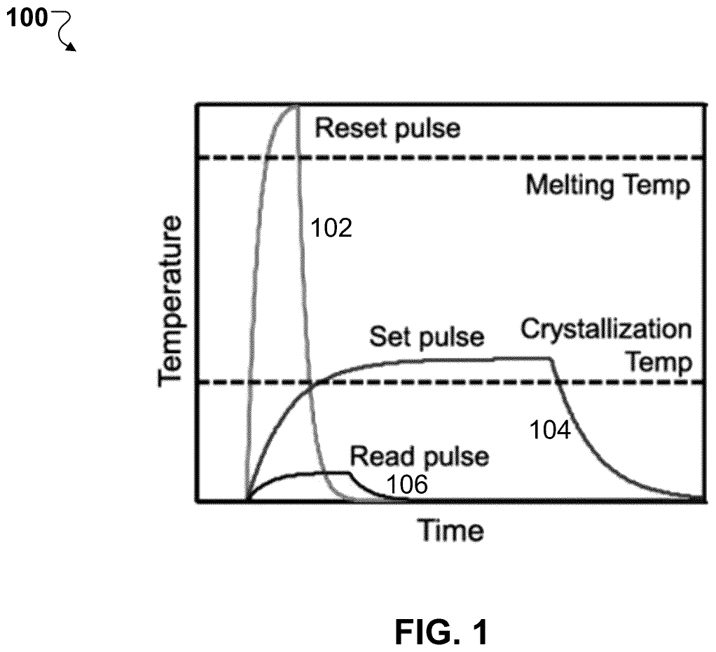

The PCM layer includes an active region in which a majority of the phase change between crystalline state and amorphous state occurs during set and reset operations. FIG. 1 illustrates an example 100 of operations of a memory element including a body of a PCM. The operations are performed by applying electrical pulses (e.g., voltage pulses), which changes a temperature of the PCM layer accordingly. During a reset operation, a fast (or short) (e.g., ˜50 ns) high-temperature pulse 102 can be used to cause the PCM within the active region that is in a low resistance crystalline state (set state) to transform to a high resistance amorphous state (or reset state). A top of the high temperature pulse 102 is beyond a melting temperature of the PCM. The fast high temperature pulse 102 can melt or breakdown the crystalline structure, after which the phase change material cools quickly, quenching the phase change process and allowing at least a portion of the phase change material to stabilize in the amorphous phase. During a set operation, a long (e.g., ˜100 ns to 10 s) medium-temperature pulse 104 is used to cause the PCM in the active region that is in a high resistance amorphous state (or reset state) to transform to a low resistance crystalline state (or set state). A top of the temperature pulse 104 is below the melting temperature but beyond a crystallization temperature of the PCM. A read pulse 106 does not generate much heat/temperature in the PCM layer, where a top of the temperature pulse 106 is below the crystallization temperature of the PCM. Such differing resistance states correspond to the storage of data within the memory cell.

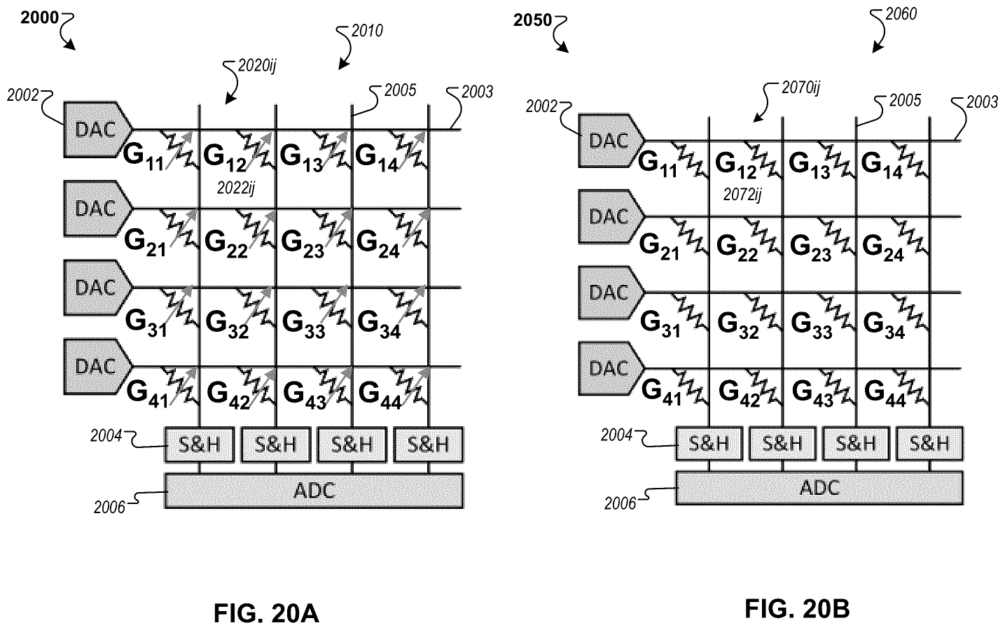

In phase change memory, data is stored by causing transitions in an active region of the phase change material between amorphous and crystalline states. The difference between a highest resistance R1 of the high resistance amorphous reset state and a lowest resistance R2 of the low resistance crystalline set state defines a read margin used to distinguish cells in the crystalline set state from those in the amorphous reset state. Also, as discussed with further details in FIG. 20B, the difference between the highest resistance R1 of the lowest resistance R2 enables the memory elements to be programmed into a plurality of resistance states that can correspond to non-overlapping ranges of resistance values. The plurality of resistance states can be used as respective weights for inference in an analog artificial intelligence (AI) system.

Hardware acceleration of deep learning using analog non-volatile memory (NVM) requires large arrays with high device yield, high accuracy Multiply-Accumulate (MAC) operations, and routing frameworks for implementing arbitrary deep neural network (DNN) topologies. Analog memory-based DNN accelerators use a variety of memories and phase-change memory is one of the best candidate memories. For the NVM-based accelerators, weights are implemented in the conductance value G of analog resistive elements, and excitations are implemented using a form of voltage or time-encoding [V(t)]. However, a drift nature (or a conductance changing over time) of PCM material is a big challenge to maintain the accuracy for DNN application. The drift nature is that the resistance levels overlap with time due to the drift of the resistance of the amorphous phase with time, following power-law.

In some examples, traditional undoped Ge2Sb2Te5 (GST)-based material shows a high drift coefficient (e.g., 0.08 to 0.1). With increasing Ge content, a drift performance degrades with a higher drift coefficient. With SiO₂ or SiC doping to the GST-based PCM material, there is no significant improvement on drift coefficient.

Implementations of the present disclosure provide techniques for managing phase change materials based on SiSbTe (SST), without and with extra SiC doping, which shows a lower drift coefficient, compared to traditional GST-based material, and can be suitable for analog AI applications, e.g., as analog accelerators. By replacing Ge with Si, PCM material based on SiSbTe shows an improved drift performance compared to the GST-based material. The SiSbTe PCM material with specific Si:Sb:Te ratios can have good drift performance (e.g., no more than 0.04), and the drift coefficient can be further decreased by extra SiC doping (e.g., no more than 0.03). For reference purposes, in the present disclosure, SiSbTe material, without and with extra SiC or any other dopants doping, is referred to as SST-based PCM material or SST family material.

Sb—Te binary alloy can be an important phase-change material. Si composition (or element) not only can improve the date retention ability and thermal stability but also retain good electrical performance. However, too much Si content may degrade the reversible phase-change ability of Sb—Te and other device parameters, because Si in the SST-based PCM material remains amorphous and does not involve the phase-change process. Suitable SiC doping can improve drift performance of SST-based PCM material and increase crystallization temperature. However, too much SiC doping may degrade the drift performance.

Besides the low drift coefficient, the SST-based PCM material can also have a high crystallization temperature (e.g., higher than 200° C.), which can prevent undesired transformation from the amorphous reset state to the crystallized set state at elevated operation temperatures to get better data retention. The SST-based PCM material can also have a low reset current (e.g., about 1 mA, compared to undoped GST-225 that requires more than 1.3 mA under same measurement conditions) to be transformed from a crystallized set state to an amorphous reset state. The SST-based PCM material can also have a fast set speed (e.g., ˜200 ns) to improve the device performance. The SST-based material can have a large resistance range (˜10⁴ to ˜10⁷ Ohm), which can be programmable to a plurality of resistance states that can correspond to non-overlapping ranges of resistance values and can be normalized as different weights for analog AI applications. For example, a full reset state refers to weight “0”, and a full set state refers to weight “1”, and any intermediate state (e.g., partial set and partial reset) corresponds to weight in a range from 0 to 1.

In some embodiments, a bulk stoichiometry of the SST-based PCM material includes: a Si atomic concentration within a range from about 7% to about 12%, a Sb atomic concentration within a range from about 27% to about 42%, a Te atomic concentration within a range from about 40% to about 60%, and/or a C atomic concentration within a range from about 10% to about 16%. Besides the ranges as disclosed herein, the techniques implemented herein can enable to develop any other suitable combinations of atomic concentrations for the compositions Si, Sb, Te, and C, e.g., for different suitable applications including data storage applications and/or analog AI applications. Besides SiC dopant, other suitable dopants (e.g., SiO₂) may be also used for the SST family to improve a drift performance, a storage performance, a read/write performance, or any other suitable performances.

The SST-based PCM materials as implemented herein can be applied to any devices or systems including elements that can be written, read, and/or erased, and can have a property (e.g., conductance/resistance) varying within a range. The techniques can be applied to two-dimensional (2D) memory devices or three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. The techniques can be applied to various types of memory systems, e.g., storage class memory (SCM), persistent memory, embedded phase change memory (PCM), 3D crosspoint memory technology, phase change random access memory (PCRAM), or any other storage systems that are based on various types of memory devices, such as static random access memory (SRAM), dynamic random access memory (DRAM), resistive random access memory (ReRAM), magnetoresistive random-access memory (MRAM), or among others. Additionally or alternatively, the techniques can be applied to systems based on, for example, SCM or PCM, such as universal flash storage (UFS), peripheral component interconnect express (PCIe) storage, embedded multimedia card (eMMC) storage, storage on dual in-line memory modules (DIMM), among others. The techniques can also be applied to magnetic disks or optical disks, among others. The techniques can be applied to any suitable applications, e.g., applications that use AI mechanisms such as artificial neural networks (ANNs) for deep learning. These applications can include gaming, natural language processing, expert systems, vision systems, speech recognition, handwriting recognition, intelligent robots, data centers, cloud computing services, and automotive applications, among others.

A PCM cell can refer to a basic device including a body of PCM material coupled between two electrodes. The PCM cell can be used as a memory element, e.g., as described with further details in FIGS. 16A-16D. Characteristics (including the drift coefficient) of a PCM material can be determined by measuring a corresponding PCM cell. For a crystalline set state, a measured resistivity or conductivity of a PCM cell is relatively stable over long service cycles. For the amorphous reset state, the resistivity (conductivity) increases (decreases) continuously and steadily over time. Reset drift coefficient can be used to indicate the stability of the resistivity or conductivity of PCM material. The reset drift coefficient depends on properties of the PCM material and also on temperature. The reset drift coefficient can be higher at an elevated temperature (e.g., 65° C.) than a room temperature (e.g., 25° C.).

In the present disclosure, a resistance drift of a PCM cell can be determined by measuring a resistance of the PCM cell in a resistance state (e.g., a reset state, a set state, or an intermediate state) over time, plotting such data in a graph of logarithm of resistance vs. logarithm of time, and thereafter calculating the slope of the plotted data. Slope, sometimes referred to as gradient in mathematics, is a number that measures the steepness and direction of a line, or a section of a line connecting two points. The slope can be essentially change in height over change in horizontal distance and is referred to as “rise over run.” The slope v can be represented mathematically as:

$$v = ( y 2 - y 1 ) / ( x 2 - x 1 ) ,$$

In the equation above, y2−y1=Δy, or vertical change in a graph, while x2−x1=Δx, or horizontal change in a graph. In the present disclosure, Δy is the change of logarithm of resistance, and Δx is the change in logarithm of time.

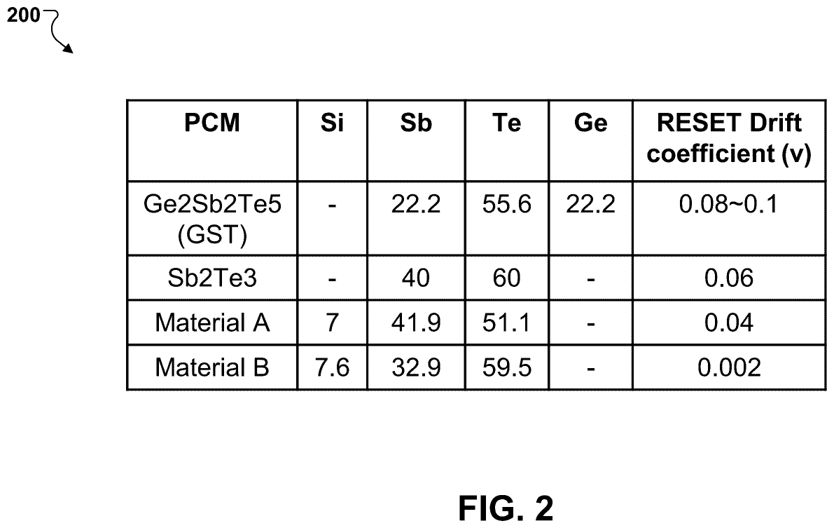

FIG. 2 illustrates a table 250 of example phase change materials with corresponding compositions (Si, Sb, Te) and reset drift coefficients (e.g., at room temperature). For comparison, characteristics (atomic percentage concentrations of compositions and reset drift coefficient) of Ge2Sb2Te5 PCM material are also listed in FIG. 2.

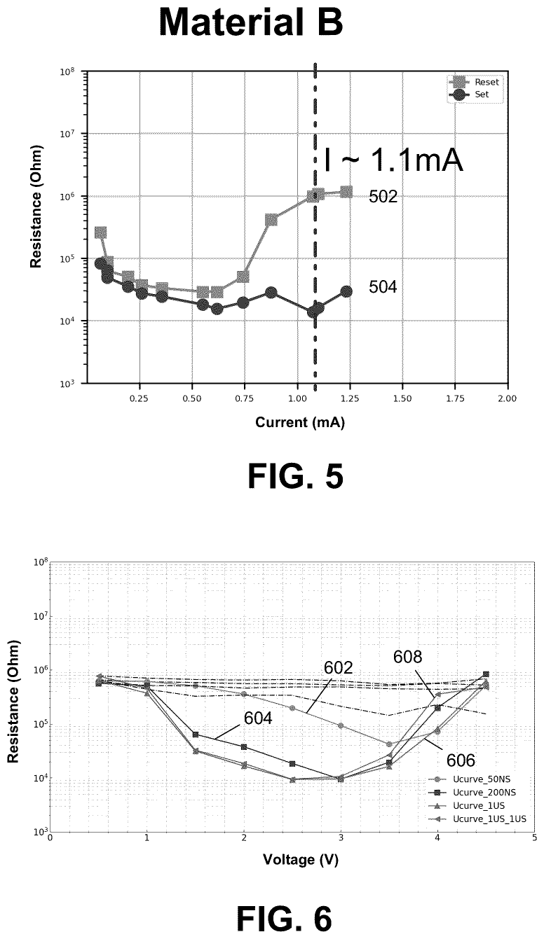

As FIG. 2 shows, by removing Ge composition, Sb2Te3 material has a lower drift coefficient (e.g., 0.06) than the Ge2Sb2Te5 material (e.g., 0.08 to 0.10). With extra Si doping (e.g., Material A and Material B), the reset drift coefficient can be even lower. For example, Material A includes Si, Sb, Te with atomic percentage concentrations of 7:41.9:51.1, and has a reset drift coefficient of about 0.04, e.g., as described with further details in FIG. 5. In comparison, Material B includes Si, Sb, Te with atomic percentage concentrations of 7.6:32.9:59.5, and has a reset drift coefficient of about 0.002, e.g., as described with further details in FIG. 6.

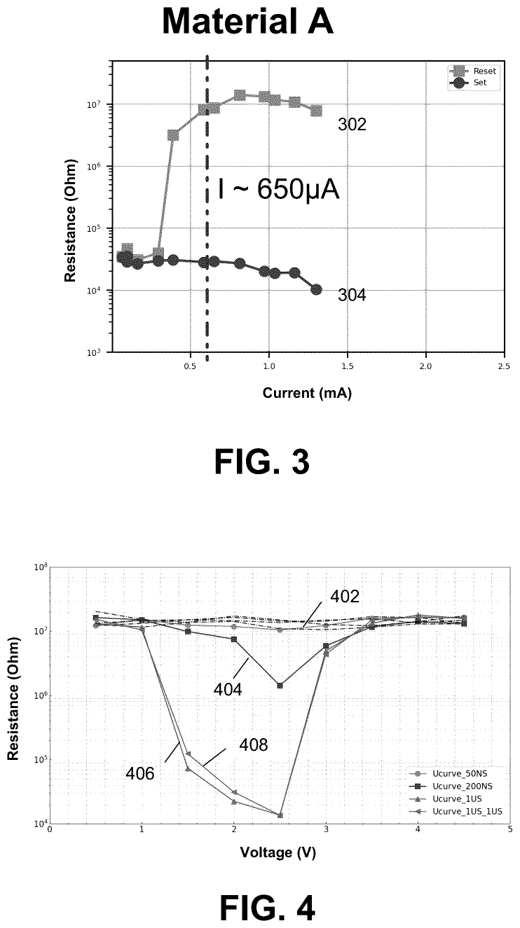

FIGS. 3-4 illustrate example performance characteristics of a PCM cell fabricated from an example SiSbTe PCM (Material A). FIG. 3 illustrates R-I curves 302, 304 for a reset state and a set state of Material A. The resistance (R) was measured when a reset current (I) was applied on the PCM cell. The reset current can correspond to a reset voltage. FIG. 3 shows that at the reset current of about 650 μA, the reset state and the set state of Material A start to have a large resistance difference (e.g., from about 2×10⁴ Ohm to about 10⁷ Ohm). The reset current (e.g., 650 μA) of Material A is lower than that of Ge2Sb2Te5 (e.g., 1.3˜1.5 mA), e.g., under same testing conditions such as using the same size of a test device.

FIG. 4 illustrates U curves 402, 404, 406, 408 showing a relationship between resistance of the PCM cell and applied set pulses (voltage value and pulse width) during set operations. A pulse width indicates a set speed. U Curve 402 shows a resistance change with a set pulse with 50 ns pulse width under different voltages, U Curve 404 shows a resistance change with a set pulse with 200 ns pulse width under different voltages, U Curve 406 shows a resistance change with a set pulse with 1 μs pulse width under different voltages, and U Curve 408 shows a resistance change with two sequential RESET/SET pulses (e.g., RESET first (such as: 6V/50 ns to RESET), and then SET pulse (such as 2V/1 μs) with 1 μs pulse width under different voltages. It shows that the set operation of Material A needs a set pulse with a pulse width longer than 200 ns, e.g., 1 μs.

FIGS. 5-6 illustrate example performance characteristics of a PCM cell fabricated from another example SiSbTe PCM (Material B). FIG. 5 illustrates R-I curves 502, 504 for a reset state and a set state of Material B. The resistance (R) was measured when a reset current (I) was applied on the PCM cell. FIG. 5 shows that at the reset current of about 1.1 mA, the reset state and the set state of Material B start to have a large resistance difference (e.g., from about 10⁴ Ohm to about 10⁶ Ohm). The reset current (e.g., ˜1.1 mA) of Material B is lower than that of Ge2Sb2Te5 (e.g., 1.3˜1.5 mA). Compared to Material B, Material A has a larger resistance difference and a lower reset current, which indicates a better performance.

FIG. 6 illustrates U curves 602, 604, 606, 608 showing a relationship between resistance of the PCM cell and applied set pulses (voltage value and pulse width) during set operations. U Curve 602 shows a resistance change with a set pulse with 50 ns pulse width under different voltages, U Curve 604 shows a resistance change with a set pulse with 200 ns pulse width under different voltages, U Curve 606 shows a resistance change with a set pulse with 1 μs pulse width under different voltages, and U Curve 608 shows a resistance change with two sequential set pulses with 1 μs pulse width under different voltages. It shows that the set operation of Material B needs a set pulse with a pulse width about 200 ns. Compared to Material A, Material B has a faster set speed.

In the following, to test a drift characteristic of a PCM material, a change of resistance of a PCM cell based on the PCM material over time at an elevated temperature (e.g., 65° C.), respectively. Meanwhile, PCM cells with the PCM material programmed to a plurality of resistance states (corresponding to a plurality of resistance values) between a full reset state (with a highest resistance value) and a full set state (with a lowest resistance value). Intermediate resistance states between the full reset state and the full set state can be partial reset (or amorphous) and partial set (or crystalline). As discussed herein, the plurality of resistance states can correspond to a plurality of conductances, which can be used as a series of weights in analog AI applications.

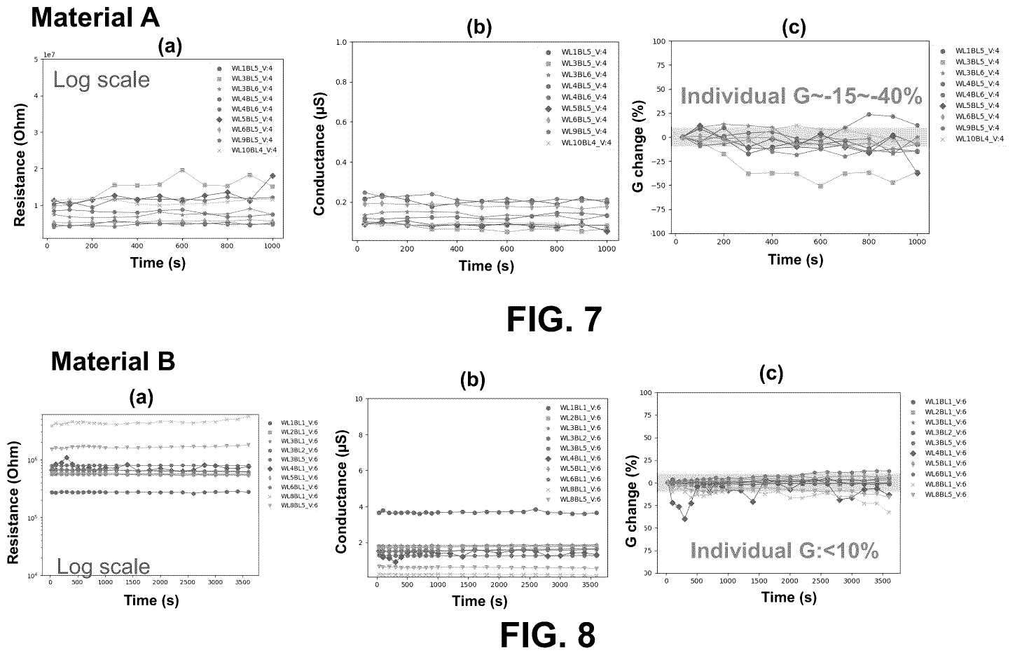

FIG. 7 illustrates drift performance characteristics (at 65° C.) of PCM cells fabricated from Material A programmed at a series of resistance states over 1 hour. The series of resistance states can be obtained by programming Material A with different voltages. Diagram (a) of FIG. 7 shows resistance changes of the series of resistance states over the time, diagram (b) of FIG. 7 shows conductance changes of the series of resistance states over the time. Conductance (G) is an inverse of resistance (R), e.g., G=1/R. Diagram (c) of FIG. 7 shows G change (%) over time of the series of resistance states. It is shown that the individual conductance change of the series of resistance states of Material A is in a range from about −15% to −40%.

FIG. 8 illustrates drift performance characteristics (at 65° C.) of PCM cells fabricated from Material B programmed at a series of resistance states over 1 hour. The series of resistance states can be obtained by programming Material B with different voltages. Diagram (a) of FIG. 8 shows resistance changes of the series of resistance states over the time, diagram (b) of FIG. 8 shows conductance changes of the series of resistance states over the time. Diagram (c) of FIG. 8 shows G change (%) over time of the series of resistance states. It is shown that the individual conductance change of the series of resistance states of Material B is less than 10%, which is more stable than that of Material A.

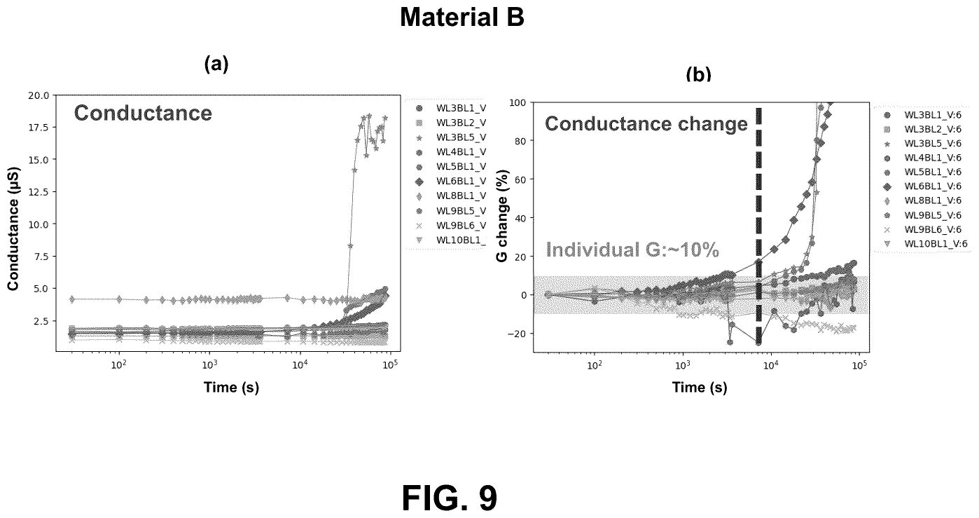

FIG. 9 illustrates drift performance characteristics (at 65° C.) of PCM cells fabricated from Material B programmed at a series of resistance states over 1 day. The series of resistance states can be obtained by programming Material B with different voltages. Diagram (a) of FIG. 9 shows conductance changes of the series of resistance states over the time. Diagram (b) of FIG. 9 shows G change (%) over time of the series of resistance states. It is shown that the conductances of the series of resistance states of Material B are stable at the elevated temperature for about 10⁴ s (˜2.8 hrs), and the corresponding G change is about 10% over the time. The conductance change becomes larger after that time.

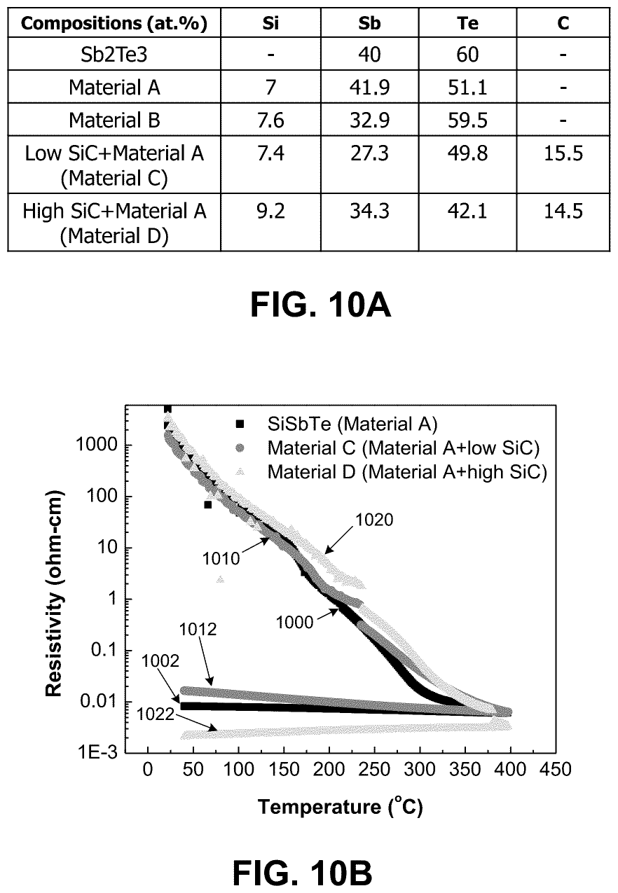

As shown above, Material A has a larger resistance difference and a lower reset current than Material B, and has a lower drift coefficient than Ge2Sb2Te5 material. To further improve the drift performance of Material A, the SiSbTe PCM material can be doped by SiC. The SiSbTe with SiC doping can be obtained by using the SiSbTe PCM material and SiC material as co-sputter targets. For example, Material C (or Material D) as shown in FIG. 10A can be formed by using Material A as a first sputter target and SiC material at a low SiC density (or a high SiC density) as a second sputter target together.

FIG. 10A illustrates example phase change materials with corresponding compositions (Si, Sb, Te, C) at various atomic concentrations. It is shown that, with low SiC doping, compared to Material A (Si:Sb:Te=7:41.9:51.1), Material C has a higher Si atomic concentration (7.4%), a lower Sb atomic concentration (27.3%), a slightly lower Te atomic concentration (49.8%), and an extra C atomic concentration (15.5%). With high SiC doping, compared to Material C, Material D has a higher Si atomic concentration (9.2%), a higher Sb atomic concentration (34.3%), a lower Te atomic concentration (42.1%), and a slightly lower C atomic concentration (14.5%). Thus, with more SiC doping, Si atomic concentration can be increased, Sb atomic concentration can be increased, Te atomic concentration can be decreased, and C atomic concentration can be decreased.

FIG. 10B illustrates resistivity of Material A, Material C, Material D of FIG. 10A with as a function of temperature. FIG. 10B shows the resistivity vs. temperature curves of Material A (trace 1000), Material C (trace 1010), and Material D (trace 1020), which can be used to determine crystallization temperatures Tx for the different materials.

As shown in FIG. 10B, the resistivity of Materials C and D begin to dramatically decrease at a temperature of around 240° C. This shows that the crystallization temperature of Material C and Material D is around 240° C. The resistivity of Material A begins to dramatically decrease at around 225° C., indicating that the crystallization temperature of Material A is around 225° C. Materials C and D have a higher crystallization temperature than Material A, thus achieving desired performance characteristics and improved data retention at elevated temperatures. That indicates that extra SiC doping into Material A (or SiSbTe PCM material) can slightly increase the crystallization temperature and accordingly achieves better data retention.

As is shown in FIG. 10B, the resistivity of Material A in a crystalline set state 1002 is below 0.01 Ω-cm. The resistivities of Material C in a crystalline set state 1012 is above 0.01 Ω-cm (about 0.02 Ω-cm) at a lower temperature and becomes smaller (e.g., to 0.01 Ω-cm) when the temperature increases. The resistivities of Material D in a crystalline set state 1022 is below 0.01 Ω-cm over the entire range of temperatures and becomes greater when the temperature increases.

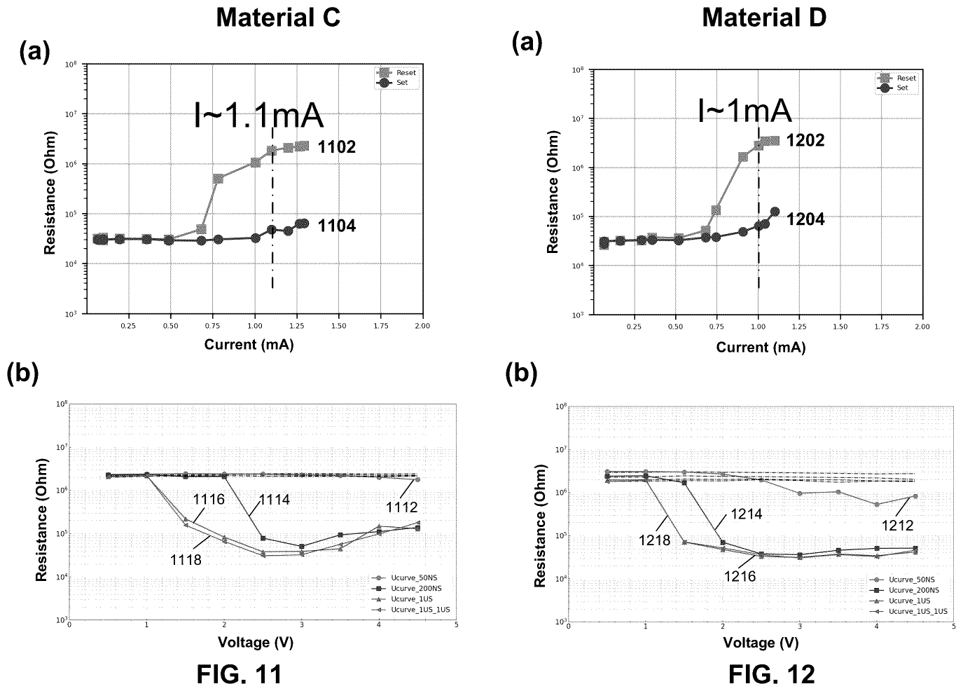

FIG. 11 illustrates example performance characteristics of a PCM cell fabricated from an example SiSbTe with low SiC doping (Material C). Diagram (a) of FIG. 11 illustrates R-I curves 1102, 1104 for a reset state and a set state of Material C. The resistance (R) was measured when a reset current (I) was applied on the PCM cell. The reset current can correspond to a reset voltage. Diagram (a) of FIG. 11 shows that at the reset current of about 1.1 mA, the reset state and the set state of Material A start to have a large resistance difference (e.g., from about 4×10⁴ Ohm to about 2×10⁶ Ohm). The reset current (e.g., 1.1 mA) of Material C is lower than that of Ge2Sb2Te5 (e.g., 1.3˜1.5 mA).

Diagram (b) of FIG. 11 illustrates U curves 1112, 1114, 1116, 1118 showing a relationship between resistance of the PCM cell and applied set pulses (voltage value and pulse width) during set operations. A pulse width indicates a set speed. U Curve 1112 shows a resistance change with a set pulse with 50 ns pulse width under different voltages, U Curve 1114 shows a resistance change with a set pulse with 200 ns pulse width under different voltages, U Curve 1116 shows a resistance change with a set pulse with 1 μs pulse width under different voltages, and U Curve 1118 shows a resistance change with two sequential set pulses with 1 μs pulse width under different voltages. It shows that the set operation of Material C needs a set pulse with a pulse width of about 200 ns.

FIG. 12 illustrates example performance characteristics of a PCM cell fabricated from an example SiSbTe with high SiC doping (Material D). Diagram (a) of FIG. 12 illustrates R-I curves 1202, 1204 for a reset state and a set state of Material D. The resistance (R) was measured when a reset current (I) was applied on the PCM cell. Diagram (a) of FIG. 12 shows that at the reset current of about 1.0 mA, the reset state and the set state of Material D start to have a large resistance difference (e.g., from about 6×10⁴ Ohm to about 3×10⁶ Ohm). The reset current (e.g., ˜1 mA) of Material D is lower than that of Ge2Sb2Te5 (e.g., 1.3˜1.5 mA). Compared to Material C, Material D has a larger resistance difference and a slightly lower reset current, which indicates a better performance.

Diagram (b) of FIG. 12 illustrates U curves 1212, 1214, 1216, 1218 showing a relationship between resistance of the PCM cell and applied set pulses (voltage value and pulse width) during set operations. U Curve 1212 shows a resistance change with a set pulse with 50 ns pulse width under different voltages, U Curve 1214 shows a resistance change with a set pulse with 200 ns pulse width under different voltages, U Curve 1216 shows a resistance change with a set pulse with 1 μs pulse width under different voltages, and U Curve 1218 shows a resistance change with two sequential set pulses with 1 μs pulse width under different voltages. It shows that the set operation of Material D needs a set pulse with a pulse width of about 200 ns, which is similar to Material C. Compared to Material A, both Material C and Material D have a faster set speed, a smaller resistance range, and a higher reset current.

In the following, to test a drift characteristic of SiSbTe PCM material with SiC doping, a change of resistance of a PCM cell based on the PCM material at an elevated temperature (e.g., 65° C.) over time (e.g., 2.8 hrs or 1 day). Meanwhile, PCM cells with the PCM material programmed to a plurality of resistance states (corresponding to a plurality of resistance values) between a full reset state (with a highest resistance value) and a full set state (with a lowest resistance value).

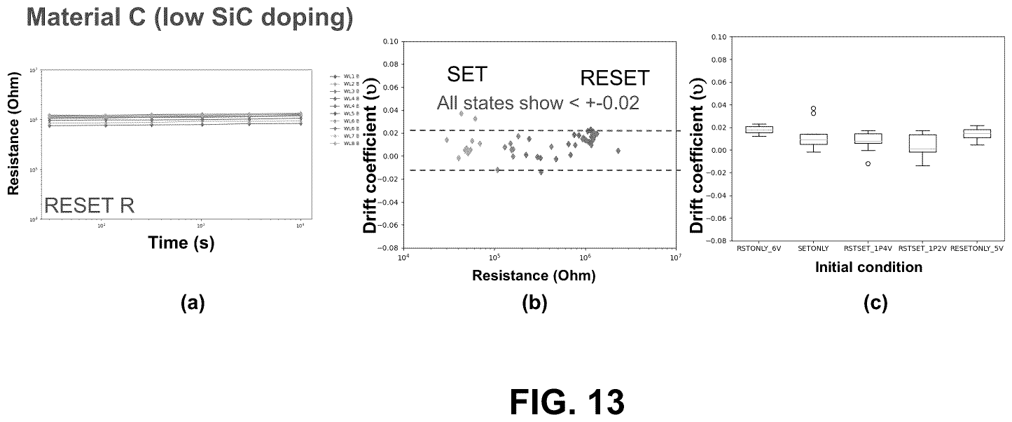

FIG. 13 illustrates drift performance characteristics (at 65° C.) of PCM cells fabricated from Material C programmed at a series of resistance states, e.g., between a set state (about 4×10⁴ Ohm) and a reset state (e.g., 2×10⁶ Ohm). The series of resistance states can be obtained by programming Material C with different voltages. As noted above, a drift coefficient of a resistance state can be obtained by plotting measurement points over time. Diagram (a) of FIG. 13 shows a resistance change of the series of resistance states of Material C over 104 seconds (or 2.8 hours), from which the drift coefficient can be calculated, respectively. Diagram (b) of FIG. 13 shows the drift coefficients from the set state to the reset state of Material C. It is shown that, for Material C, a total drift coefficient is less than +/−0.02, which is lower than that of Material A even at room temperature (e.g., about 0.04). Diagram (c) of FIG. 13 shows a distribution of the drift coefficient for each state (including the set state, the reset state, and the intermediate states). The reset drift coefficient for Material C is about 0.02, which is lower than that of Material A even at room temperature (e.g., about 0.04).

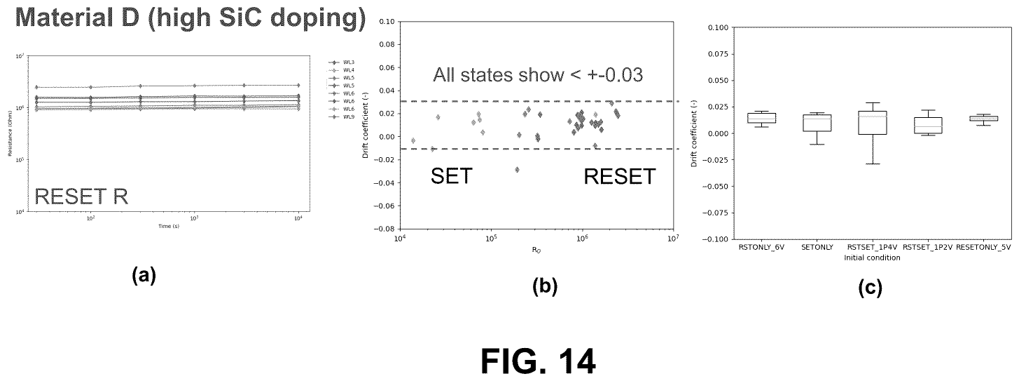

FIG. 14 illustrates drift performance characteristics (at 65° C.) of PCM cells fabricated from Material D programmed at a series of resistance states, e.g., between a set state (about 4×10⁴ Ohm) and a reset state (e.g., 2×10⁶ Ohm). The series of resistance states can be obtained by programming Material D with different voltages. As noted above, a drift coefficient of a resistance state can be obtained by plotting measurement points over time. Diagram (a) of FIG. 14 shows a resistance change of the series of resistance states of Material D over 104 seconds (or 2.8 hours), from which the drift coefficient can be calculated, respectively. Diagram (b) of FIG. 14 shows the drift coefficients from the set state to the reset state of Material D. It is shown that, for Material D, a total drift coefficient is less than +/−0.03, which is lower than that of Material A even at room temperature (e.g., about 0.04). Diagram (D) of FIG. 14 shows a distribution of the drift coefficient for each state (including the set state, the reset state, and the intermediate states). The reset drift coefficient for Material D is about 0.03, which is lower than that of Material A even at room temperature (e.g., about 0.04). Compared to Material D, Material C exhibits a lower reset drift coefficient. The result show that SiC doping can improve drift performance. With higher SiC doping, the drift performance may slightly decrease.

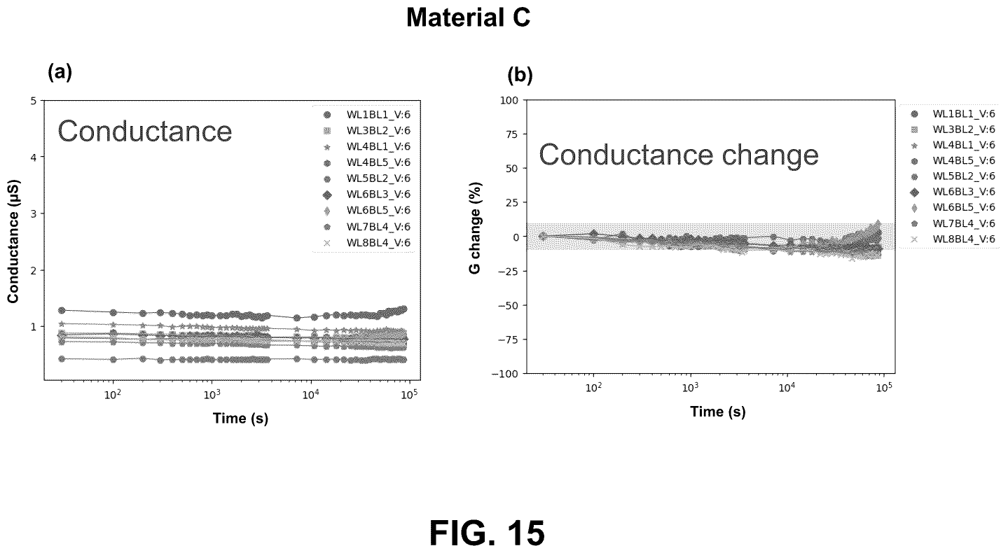

FIG. 15 illustrates drift performance characteristics (at 65° C.) of PCM cells fabricated from Material C programmed at a series of states over 1 day. The series of resistance states can be obtained by programming Material C with different voltages. Diagram (a) of FIG. 15 shows conductance changes of the series of resistance states over the time. Diagram (b) of FIG. 15 shows G change (%) over time of the series of resistance states. It is shown that the conductances of the series of resistance states of Material C are stable at the elevated temperature over 1 day, and the corresponding G change of the series of states is about 10% over 1 day, which exhibits better drift performance than Material B (as shown in FIG. 9).

Note that Material A, Material B, Material C, and Material D as described in the present disclosure are just examples of SST-based PCM materials or SST family materials. Other suitable combinations of atomic percentage concentrations for different compositions (Si, Sb, Te, C) may be also suitable for improving the drift performance and/or any other performances (e.g., high crystallization temperature, low reset current, fast reset speed, fast set speed, and/or large resistance range). The total of the atomic percentage concentrations of the different compositions is 100%.

For example, an SST-based PCM material can include Si with the atomic percentage concentration in a first range between a minimum concentration and a maximum concentration. The minimum concentration of the first range can be about 1%, 2%, 3%, 4%, 5%, 6%, 7%, or 8%, and the maximum concentration of the second range can be 9%, 10%, 11%, 12%, 13%, 14%, 15%, 16%, 17%, 18%, 19%, or 20%. In an example, the first range is from about 7% to about 12%. The SST-based PCM material can also include Sb with the atomic concentration within a second range. A minimum concentration of the second range can be about 20%, 21%, 22%, 23%, 24%, 25%, 26%, 27%, 28%, 29%, or 30%, and a maximum concentration of the second range can be about 31%, 32%, 33%, 34%, 35%, 36%, 37%, 38%, 39%, 40%, 41%, 42%, 43%, 44%, 45%. In an example, the second range is from about 27% to about 42%. The SST-based PCM material can also include Te with the atomic concentration within a third range. A minimum concentration of the third range can be about 35%, 36%, 37%, 38%, 38%, 39%, 40%, 41%, 42%, 43%, 44%, or 45%, and a maximum concentration of the third range can be about 50%, 51%, 52%, 53%, 54%, 55%, 56%, 57%, 58%, 59%, 60%, 61%, 62%, 63%, 64%, or 65%. In an example, the third range is from about 40% to about 60%. The SST-based PCM material can also include C with the atomic concentration within a fourth range. A minimum concentration of the fourth range can be about 5%, 6%, 7%, 8%, 9%, 10%, 11%, 12%, 13%, 14%, or 15%, and a maximum concentration of the fourth range can be about 15%, 16%, 17%, 18%, 19%, or 20%. In an example, the fourth range is from about 10% to about 16%.

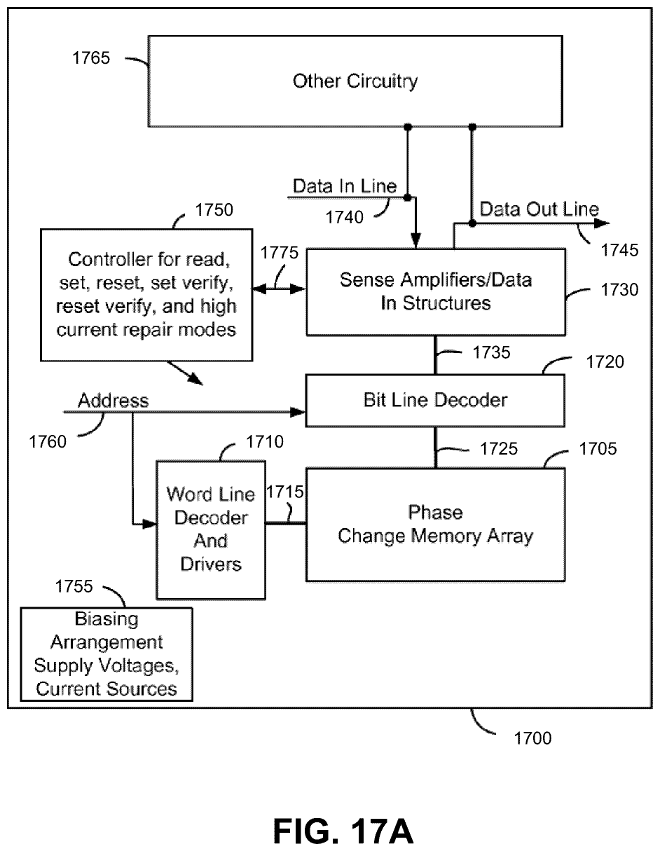

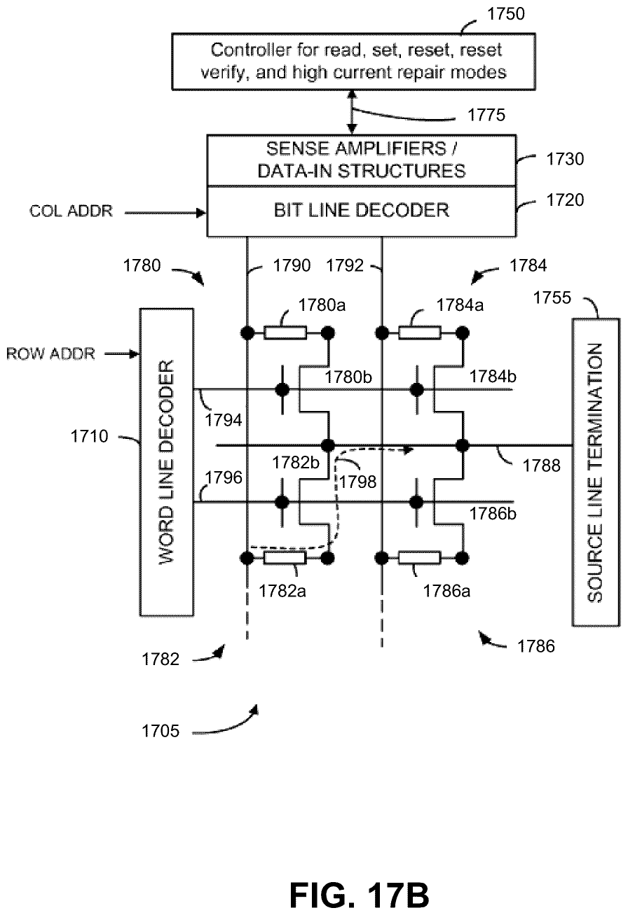

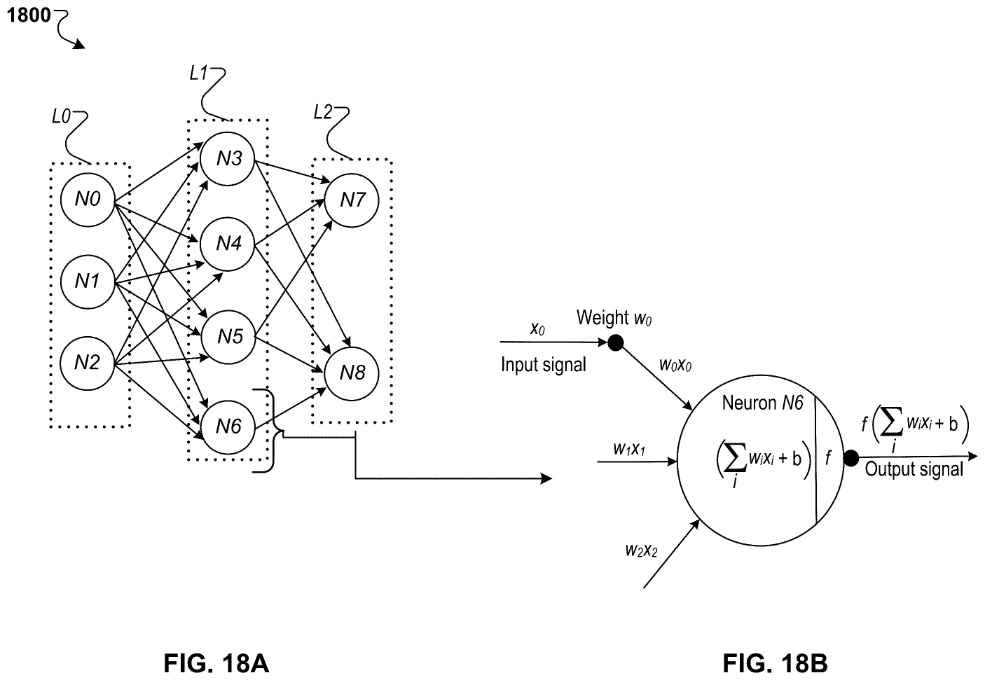

The PCM materials as described herein (e.g., SST-based PCM material with good drift performance) can be used to develop memory elements, e.g., as described with further details in FIGS. 16A-16D. The memory elements can be used to form phase change memory devices with good drift performance, e.g., as described with further details in FIGS. 17A-17B. The phase change memory devices with good drift performance can be used in analog AI systems, e.g., as described with further details in FIGS. 18A-20B.

FIG. 16A illustrates a cross-sectional view of an example memory element 1600 made from a PCM material with a mushroom-type structure. The PCM material can be an SST-based PCM material such as Material A, Material B, Material C, Material D, or any other SST-based PCM material as described herein.

In some embodiments, e.g., as illustrated in FIG. 16A, the memory element 1600 includes a memory body 1602 of the PCM material as a memory material. The memory element 1600 includes an active region 1604. The memory element 1600 includes a first electrode 1606 extending through a dielectric layer 1608 to contact a bottom surface of the memory body 1602. A second electrode 1610 is formed on the memory body 1602 to create a current between the first electrode 1606 and second electrode 1610 through the memory body 1602. The first and second electrodes 1606 and 1610 may include, for example, TiN or TaN. Alternatively, the first and second electrodes 1606 and 1610 may each be W, WN, TiAlN or TaAlN, or include, for further examples, one or more elements selected from the group consisting of doped-Si, Si, C, Ge, Cr, Ti, W, Mo, Al, Ta, Cu, Pt, Ir, La, Ni, N, O, and Ru and combinations thereof. The dielectric layer 1608 can include silicon nitride, silicon oxynitride, silicon oxide and any other suitable dielectric material.

The described memory element 1600 has a first electrode 1606 with a relatively narrow width (or diameter) 1612. The narrow width 1612 of the first electrode 1606 results in an area of contact between the first electrode 1606 and the memory body 1602 that is less than the area of contact between the memory body 1602 and the second electrode 1610. Thus, current is concentrated in the portion of the memory body 1602 adjacent the first electrode 1606, resulting in the active region 1604 being in contact with or near the first electrode 1606, as shown. The memory body 1602 also includes an inactive region outside the active region 1604, which is inactive in the sense that it does not undergo phase transitions during operation. Even though the inactive region outside of the active region 1604 does not undergo phase transformations during device operation the bulk stoichiometry of the entire memory body 1602 including the active region 1604 and the inactive region includes the PCM material.

FIG. 16B illustrates across-sectional view of an example memory element 1630 made from a PCM material with an “active in via” type structure. The PCM material can be an SST-based PCM material such as Material A, Material B, Material C, Material D, or any other SST-based PCM material as described herein.

In some embodiments, e.g., as illustrated in FIG. 16B, the memory element 1630 includes a memory body 1632 of the PCM material in an inter-electrode current path through memory body 1632. The memory body 1632 is in a pillar shape and contacts first and second electrodes 1634 and 1636 at top and bottom surfaces 1638 and 1640, respectively. The memory body 1632 has a width 1644 substantially the same as that of the first and second electrodes 1634 and 1636 to define a multi-layer pillar surrounded by dielectric (not shown). As used herein, the term “substantially” is intended to accommodate manufacturing tolerances. In operation, as current passes between the first and second electrodes 1634 and 1636 and through the memory body 1632, the active region 1642 heats up more quickly than the other regions within the memory element. This leads to a majority of the phase transformation occurring within the active region during device operation.

FIG. 16C illustrates across-sectional view of an example memory element 1650 made from a PCM material with a pore type structure. The PCM material can be an SST-based PCM material such as Material A, Material B, Material C, Material D, or any other SST-based PCM material as described herein.

The memory element 1650 includes a memory body 1652 of the PCM material in an inter-electrode current path through the memory body 1652. The memory body 1652 is surrounded by dielectric (not shown) contacting first and second electrodes 1654 and 1656 at top and bottom surfaces 1658 and 1660, respectively. The memory body 1652 has a varying width 1662 that is always less than the width of the first and second electrodes. In operation, as current passes between the first and second electrodes 1654 and 1656 and through the memory body 1652 the active region 1664 heats up more quickly than the remainder of the memory element. Thus, the volume of memory body 1652 within the active region is where a majority of the phase transformation occurs during device operation.

FIG. 16D illustrates a cross-sectional view of example memory structure 1670 including multiple memory elements 1670a made from a PCM material with a cross-point structure. The PCM material can be an SST-based PCM material such as Material A, Material B, Material C, Material D, or any other SST-based PCM material as described herein.

Each memory element 1670a includes a memory body 1672 of the PCM material, a first electrode 1674, and a second electrode 1676. A switch layer 1678 can be positioned between the first electrode 1674 and the memory body 1672. As shown in FIG. 16D, in the cross-point structure, the first electrode 1674 can be shared by multiple memory elements 1670a along a first direction (e.g., Y direction), the second electrode 1676 can be shared by multiple memory elements 1670a along a second direction (e.g., X direction), and the multiple memory elements can be stacked along a third direction (e.g., Z direction).

As will be understood, the PCM material as described herein, can be used in a variety of memory element structures and is not limited to the memory element structures described herein.

The memory elements (e.g., 1600 of FIG. 16A, 1630 of FIG. 16B, 1650 of FIG. 16C, or 1670 of FIG. 16D) can be used to form a phase change memory device, e.g., as described with further details in FIGS. 17A-17B.

FIG. 17A illustrates an integrated circuit 1700 including an array of phase change memory cells. The integrated circuit 1700 can be a phase change memory device. The integrated circuit 1700 includes a phase change memory array 1705 of phase change memory cells which can be operated as described herein. A word line decoder and drivers 1710 having read, set, reset, set verify, reset verify and high current repair modes is coupled to and in electrical communication with a plurality of word lines 1715 arranged along rows in the phase change memory array 1705. A bit line (column) decoder 1720 is in electrical communication with a plurality of bit lines 1725 arranged along columns in the array 1705 for reading data from, and writing data to, the phase change memory cells in the array 1705. Addresses are supplied on bus 1760 to word line decoder and drivers 1710 and bit line decoder 1720. Sense circuitry (sense amplifiers) and data-in structures in block 1730 are coupled to bit line decoder 1720 via data bus 1735. Data is supplied via a data-in line 1740 from input/output ports on the integrated circuit 1700, or from other data sources internal or external to the integrated circuit 1700, to data-in structures in block 1730. Other circuitry 1765 may be included on the integrated circuit 1700, such as a general purpose processor or special purpose application circuitry, or a combination of modules providing system-on-a-chip functionality supported by the phase change array 1705. Data is supplied via a data-out line 1745 from the sense amplifiers in block 1730 to input/output ports on the integrated circuit 1700, or to other data destinations internal or external to the integrated circuit 1700.

The integrated circuit 1700 includes a controller 1750 for read, set, reset, set verify, reset verify and high current repair modes. The controller 1750, implemented in this example using a bias arrangement state machine, controls the application of bias arrangement supply voltages and current sources 1755 for the application of bias arrangements including read, set, reset, set verify, reset verify and high current repair modes. The controller 150 is coupled to the sense amplifiers in block 1775 for controlling the biasing arrangement supply voltages and current sources 1755 in response to output signals from the sense amplifiers in block 1730. Controller 1750 may be implemented using special-purpose logic circuitry as known in the art. In alternative embodiments, controller 1750 comprises a general-purpose processor, which may be implemented on the same integrated circuit to execute a computer program to control the operations of the integrated circuit 1700.

FIG. 17B illustrates an example of operating a portion of phase change memory cells in the phase change memory array 1705 of FIG. 17A. As shown in FIG. 17B, each of the memory cells includes a memory element (e.g., the memory element 1600 of FIG. 16A, 1630 of FIG. 16B, 1650 of FIG. 16C or 1670 of FIG. 16D, or any PCM cell as described herein) and an access device (e.g., a transistor, a diode, or a selector switch). The memory element can be used as a resistance element. The memory cell can have a 1S1R structure including a selector element and a resistance element.

As illustrated in FIG. 17B, four memory cells 1780, 1782, 1784, 1786 have respective phase change memory elements 1780a, 1782a, 1784a, 1786a and respective access devices 1780b, 1782b, 1784b, 1786b. The memory cells can be programmable to a plurality of resistance states including a high resistance state (e.g., a reset state) and a low resistance state (e.g., a set state). The resistance states correspond to non-overlapping ranges of resistance values for the corresponding phase change memory elements.

In some embodiments, sources of each of the access transistors of the memory cells 1780, 1782, 1784, 1786 are connected in common to a source line 1788 that terminates in a source line termination circuit 1755. In another embodiment, the sources of the access devices are not electrically connected, but independently controllable. The source line termination circuit 1755 may for example be a ground terminal. Alternatively, in some embodiments the source line termination circuit 1755 may include bias circuits such as voltage sources and current sources, and decoding circuits for applying bias arrangements, other than ground, to the source line 1788.

A plurality of word lines including word lines 1794, 1796 extend in parallel along a first direction. The word lines 1794, 1796 are in electrical communication with word line decoder 1710. The gates of access transistors of memory cells 1780, 1784 are connected to word line 1794. The gates of access transistors of memory cells 1782, 1786 are connected to word line 1796. A plurality of bit lines including bit lines 1790, 1792 extend in parallel along a second direction. The bit lines 1790, 1792 are in electrical communication with bit line decoder 1720. Memory elements 1780a, 1782a couple the bit line 1790 to the respective drains of the access transistors of memory cells 1780, 1782. Memory elements 1784a, 1786a couple the bit line 1792 to the respective drains of the access transistors of memory cells 1784, 1786.

It will be understood that the memory array 1705 is not limited to the array configuration illustrated in FIG. 17B, and other array configurations may be used. Additionally, instead of MOS transistors, bipolar transistors or diodes may be used as access devices in some embodiments.

In operation, each of the memory cells 1780, 1782, 1784, 1786 store a data value depending upon the resistance of their respective memory elements 1780a, 1782a, 1784a, 1786a. The data value may be determined, for example, by comparison of current on a bit line for a selected memory cell to that of a suitable reference current. In a memory cell programmable to three or more resistance states, a plurality of reference currents can be established so that different ranges of bit line currents corresponding to each of the three or more resistance states.

Reading or writing to a selected memory cell of the array 1705 can be achieved by applying a suitable voltage to the corresponding word line and coupling the corresponding bit line to a bias voltage so that current flows through the selected memory cell including through the respective memory element. For example, a current path 1798 through a selected memory cell 1782 is established by applying bias voltages to the bit line 1790, word line 1796, and source line 1788 sufficient to turn on the access transistor of the memory cell 1782 and induce current in path 1798 from the bit line 1790 to the source line 1788, or vice versa.

In a read (or sense) operation of memory cell 1782, a bias voltage is applied across the selected memory cell to induce a current through the memory element. The current does not cause the memory element to undergo a change in resistive state. The magnitude of the current through the memory element is dependent upon the resistance of the memory element and thus the data value stored in the memory cell 1782. Therefore, the current that is induced serves to read the memory cell as the magnitude of such current depends on what resistive state the memory element is in corresponding to a stored or lack thereof data value.

FIGS. 18A and 18B illustrate an example of an artificial neural network (ANN) 1800 and an exploded view of a neuron N6 of the ANN 1800, respectively. As shown in FIG. 18A, the ANN 100 is a collection of connected units or nodes, e.g., N0, N1, N2, N3, N4, N5, N6, N7 and N8, which are called artificial neurons. The artificial neurons are organized in layers. For example, layer L0 includes artificial neurons N0, N1 and N2; layer L1 includes artificial neurons N3, N4, N5 and N6; and layer L2 includes artificial neurons N7 and N8.

In some implementations, different layers of an ANN perform different kinds of transformations on their inputs. One of the layers is a first or input layer of the ANN, e.g., layer L0, while another layer is a last or output layer of the ANN, e.g., layer L2. The ANN includes one or more internal layers, e.g., layer L1, between the input layer and the output layer. Signals travel from the input layer to the output layer, after traversing the internal layers one or more times.

In some implementations, each connection between artificial neurons, e.g., a connection from N2 to N6, or from N6 to N8, can transmit a signal from one to another. The artificial neuron that receives the signal can process it and then signal artificial neurons connected to it. In some implementations, the signal at a connection between artificial neurons is a real number, and the output of each artificial neuron is calculated by a non-linear function of the sum of its inputs. Each connection can have a weight that adjusts as learning proceeds. The weight increases or decreases the strength of the signal at a connection.

In some implementations, a set of input data (e.g., from each sample) is presented to an ANN, e.g., at an input layer like L0. A series of computations is performed at each subsequent layer such as L1. In the fully-connected network illustrated in FIG. 18A, an output computation from each node is presented to all nodes in the subsequent layer. The final layer such as L2 of the trained ANN can be associated with determining a classification match to the input data, e.g., from a fixed set of labeled candidates, which can be referred to as “supervised learning.”

FIG. 18B shows an exploded view of a computation performed at an artificial neuron N6, which is an example of artificial neurons in an ANN. Input signals x₀, x₁ and x₂ from other artificial neurons of the ANN 1800, e.g., from artificial neurons N0, N1 and N2 respectively, are sent to the artificial neuron N6. Each input signal is weighted by a weight associated with the corresponding connection, and the weighted signal is received and processed by the artificial neuron. For example, the connection from artificial neuron N0 to artificial neuron N6 has a weight w₀ that weights the signal x₀ sent from N0 to N6 via the connection, such that the value of the signal received and processed by N6 is w₀x₀. Similarly, the connections from artificial neurons N1 and N2 to artificial neuron N6 have weights w₁ and w₂ respectively, such that the value of the signals received by N6 from N1 and N2 are w₁x₁ and w₂x₂, respectively.

An artificial neuron processes the weighted input signals internally, e.g., by changing its internal state (referred to as activation) according to the input, and produces an output signal depending on the input and the activation. For example, the artificial neuron N6 produces an output signal that is a result of output function ƒ that is applied to the weighted combination of the input signals received by the artificial neuron N6. In this manner, the artificial neurons of the ANN 1800 form a weighted, directed graph that connects the outputs of some neurons to the inputs of other neurons. In some implementations, the weights, the activation function, the output function, or any combination of these parameters of an artificial neuron, can be modified by a learning process, e.g., deep learning.

In some implementations, the computation is a multiply-accumulate (MAC) calculation, which can be an action in the AI operation. As illustrated in FIG. 18B, each data value xᵢ of a plurality of input signals is multiplied by its related weight wᵢ, then summed to obtain Σᵢwᵢxᵢ, and a final bias value b may be added to obtain a computed value z=(Σᵢwᵢxᵢ+b). Then, the computed value z is calculated through an activation function ƒ to obtain an output value a=ƒ(Σᵢwᵢxᵢ+b). The output value a can be provided as a node output (or an output signal) to the next layer as an input.

An AI model, e.g., the ANN 1800, can be operated in a training mode and an inference mode. For the AI model to provide an answer to a problem, the connections between the answer and the problem can be addressed by repeatedly exercising network training. In the training mode, initially the AI model is given a set of test data with correct labels, known as training data. Then, the inference of the AI model generated by the set of test data is monitored, to which the AI model can respond truthfully or falsely. The aim of the learning method is to detect patterns, and what the AI model does in this case is to search and group the data according to their similarity. The AI training mode can be similar to a training in multimedia data processing. Mathematically, in the training mode, weights in the AI model are adjusted to get a maximized output. In the inference mode, the AI model is put into practice based on what the AI model has learned in training. The AI model can create an inference model with trained and fixed weights to classify, solve, and/or answer the problem.

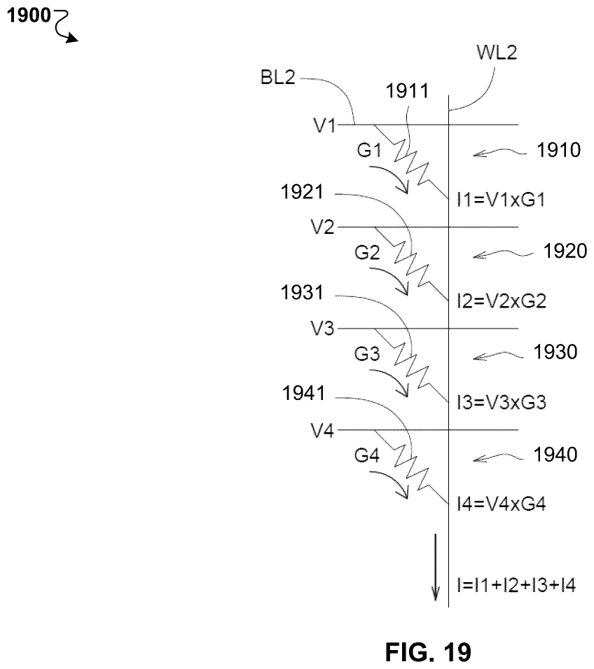

FIG. 19 shows an example memory 1900 for performing a multiply-accumulate calculation (MAC). The memory 1900 can be a phase change memory device as described in the present disclosure, e.g., the integrated circuit 1700 in FIGS. 17A-17B. The memory 1900 can include a phase change memory array (e.g., 1705 of FIGS. 17A-17B) that includes, for example, a plurality of memory cells 1910, 1920, 1930, 1940 (e.g., 1780, 1782, 1784, 1786 of FIG. 17B). A memory cell can include a memory element, e.g., 1600 of FIG. 16A, 1630 of FIG. 16B, 1650 of FIG. 16C, 1670 of FIG. 16D, 1780a, 1782a, 1784a, or 1786a of FIG. 17B, or any PCM cell as described herein. The memory cells 1910, 1920, 1930, 1940 include, for example, memory elements 1911, 1921, 1931, 1941 as respective resistors corresponding to respective conductances G1, G2, G3, G4.

When voltages V1, V2, V3, V4 are respectively inputted to a bit line BL2, a plurality of respective read currents I1, I2, I3, I4 flow into a word line WL2. The read current I1 is equivalent to a product of the voltage V1 and the conductance G1; the read current I2 is equivalent to a product of the voltage V2 and the conductance G2; the read current I3 is equivalent to a product of the voltage V3 and the conductance G3; the read current I4 is equivalent to a product of the voltage V4 and the conductance G4. A total current I is equivalent to a sum of products of the voltages V1, V2, V3, V4 and the conductances G1, G2, G3, G4. If the voltages V1, V2, V3, V4 represent the input signals xᵢ, and the conductances G1, G2, G3, G4 represent the weights wᵢ, then the total current I represents the sum of the products of the input signals xᵢ and the weights wᵢ as described in the following equation (1):

$$I = {\sum }_{i} ( {w}_{i} * {x}_{i} ) = {\sum }_{i} ( {G}_{i} * {V}_{i} ) \qquad ( 1 )$$

Through the memory 1900 in FIG. 19, an MAC in the artificial intelligence operation can be realized.

FIG. 20A illustrates an example system 2000 for executing a training mode. The system 2000 includes a memory 2010 that includes, for example, a plurality of memory cells 2020ᵢⱼ arranged in a matrix. The system 2000 can further include a plurality of digital to analog converter (DAC) 2002 each coupled to a respective bit line 2003 (e.g., the bit line BL2 of FIG. 19). Each DAC 2002 is configured to convert an input digital signal, e.g., voltage such as V1, V2, V3, V4 of FIG. 19, into an analog voltage signal. The system 2000 can also include a plurality of sampling & holding (SH) unit 2004 each coupled to a respective word line 2005 (e.g., the word line WL2 of FIG. 19) and an analog to digital converter (ADC) 2006 coupled to the plurality of SH units 2004. Each SH unit 2004 can include one or more logic units and/or circuits configured to sample and hold a summed current analog signal (e.g., I in FIG. 19) along the respective word line 2005, and the ADC 2006 can be configured to sum up the summed current analog signal from each word line 2005 and convert the final sum result from an analog signal into a digital signal for further processing.

Each of the memory cells 2020ᵢⱼ can have an adjustable resistor 2022ᵢⱼ, for example. Each of the adjustable resistors 2022ᵢⱼ has a conductance Gᵢⱼ. These conductances Gᵢⱼ can be used to represent the weights wᵢⱼ, e.g., wᵢ as illustrated in FIG. 18B. When the memory 2010 executes a training mode, the weights wᵢⱼ need to be updated continuously, so the memory 2010 with the adjustable resistors 2022ᵢⱼ can be used to execute the training mode smoothly.

FIG. 20B illustrates an example system 2050 for executing an inference mode. The system 2050 is similar to the system 2000 and includes DACs 2002, S&H units 2004 and ADC 2006. Different from the system 2000 of FIG. 20A, the system 2050 includes a memory 2060 that is different from the memory 2010. The memory 2060 includes, for example, a plurality of memory cells 2070ᵢⱼ arranged in a matrix. Each of the memory cells 2070ᵢⱼ has a fixed resistor 2072ᵢⱼ, for example, which is different from the memory 2020ij with an adjustable resistor 2022ᵢⱼ. Each of the fixed resistors 2022ᵢⱼ has a fixed conductance Gᵢⱼ. These conductances Gᵢⱼ can be used to represent fixed weights wᵢⱼ. In the process of executing the inference mode, the weights wᵢⱼ have already been set and are not changed arbitrarily, e.g., based on trained Gᵢⱼ of FIG. 20A, so the memory 2060 with the fixed resistors 2072ᵢⱼ can be used to execute the inference mode smoothly. Thus, it is desirable to have the memory 2060 that has non-volatility and good retention to keep the weights fixed with low power consumption for AI inference. The memory 2060 can be implemented by a phase change memory device as described in the present disclosure, e.g., the integrated circuit 1700 of FIGS. 17A-17B. The memory cell 2070ᵢⱼ can be implemented by the memory cell as described in the present disclosure, e.g., 1780, 1782, 1784,1786 of FIG. 17B. The fixed resistors 2022ᵢⱼ can be implemented by the memory elements as described in the present disclosure, e.g., 1600 of FIG. 16A, 1630 of FIG. 16B, 1650 of FIG. 16C, 1670 of FIG. 16D, 1780a, 1782a, 1784a, or 1786a of FIG. 17B, or any PCM cell as described herein.

The disclosed and other examples can be implemented as one or more computer program products, for example, one or more modules of computer program instructions encoded on a computer readable medium for execution by, or to control the operation of, data processing apparatus. The computer readable medium can be a machine-readable storage device, a machine-readable storage substrate, a memory device, or a combination of one or more them. The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them.

A system may encompass all apparatus, devices, and machines for processing data, including by way of example a programmable processor, a computer, or multiple processors or computers. A system can include, in addition to hardware, code that creates an execution environment for the computer program in question, e.g., code that constitutes processor firmware, a protocol stack, a database management system, an operating system, or a combination of one or more of them.

A computer program (also known as a program, software, software application, script, or code) can be written in any form of programming language, including compiled or interpreted languages, and it can be deployed in any form, including as a standalone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed for execution on one computer or on multiple computers that are located at one site or distributed across multiple sites and interconnected by a communications network.

The processes and logic flows described in this document can be performed by one or more programmable processors executing one or more computer programs to perform the functions described herein. The processes and logic flows can also be performed by, and apparatus can also be implemented as, special purpose logic circuitry, e.g., an FPGA (field programmable gate array) or an ASIC (application specific integrated circuit).

Processors suitable for the execution of a computer program include, by way of example, both general and special purpose microprocessors, and any one or more processors of any kind of digital computer. Generally, a processor will receive instructions and data from a read only memory or a random access memory or both. The essential elements of a computer can include a processor for performing instructions and one or more memory devices for storing instructions and data. Generally, a computer can also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data can include all forms of nonvolatile memory, media and memory devices, including by way of example semiconductor memory devices, e.g., EPROM, EEPROM, and flash memory devices, and magnetic disks. The processor and the memory can be supplemented by, or incorporated in, special purpose logic circuitry.

While this document may describe many specifics, these should not be construed as limitations on the scope of an invention that is claimed or of what may be claimed, but rather as descriptions of features specific to particular embodiments. Certain features that are described in this document in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination in some cases can be excised from the combination, and the claimed combination may be directed to a sub-combination or a variation of a sub-combination. Similarly, while operations are depicted in the drawings in a particular order, this should not be understood as requiring that such operations be performed in the particular order shown or in sequential order, or that all illustrated operations be performed, to achieve desirable results.

Only a few examples and implementations are disclosed. Variations, modifications, and enhancements to the described examples and implementations and other implementations can be made based on what is disclosed.

What is claimed is:

1. An integrated circuit, comprising:
a first electrode;
a second electrode; and
a body of a phase change material coupled between the first electrode and the second electrode,
wherein the phase change material comprises SiₓSb_{y}Te_{z}, where x, y, z represent respective atomic ratios for compositions Si, Sb, Te, and
wherein a bulk stoichiometry of the body of the phase change material comprises a Si atomic concentration within a range from about 7% to about 12%.

2. The integrated circuit of claim 1, wherein the bulk stoichiometry of the body of the phase change material comprises:
a Sb atomic concentration within a range from about 27% to about 42%, and
a Te atomic concentration within a range from about 40% to about 60%.

3. The integrated circuit of claim 1, wherein the phase change material comprises SiC doped in SiₓSb_{y}Te_{z}.

4. The integrated circuit of claim 3, wherein the bulk stoichiometry of the body of the phase change material comprises:
a C atomic concentration within a range from about 10% to about 16%.

5. The integrated circuit of claim 1, wherein the body of the phase change material has a thickness in a range from 30 nm to 80 nm.

6. The integrated circuit of claim 1, wherein a reset drift coefficient of the integrated circuit at a room temperature is no more than 0.04.

7. The integrated circuit of claim 1, wherein a reset drift coefficient of the integrated circuit at an elevated temperature is no more than 0.04.

8. The integrated circuit of claim 1, wherein a change of a conductance of the integrated circuit at an elevated temperature is no more than 10% over 1 hour.

9. The integrated circuit of claim 1, wherein a change of a conductance of the integrated circuit at an elevated temperature is no more than 10% over 1 day.

10. The integrated circuit of claim 1, wherein the body of the phase change material is programmable to a plurality of resistance states including a full reset state and a full set state, and
wherein a change of a conductance of each of the plurality of resistance states is no more than 10% over 1 day.

11. The integrated circuit of claim 1, wherein the phase change material has a crystallization temperature greater than 200° C.

12. The integrated circuit of claim 1, wherein the body of a phase change material is configured to be applied with a set pulse having a duration of no more than 200 ns to change the phase change material from an amorphous phase to a crystalline phase.

13. The integrated circuit of claim 1, configured to be a memory element with a mushroom type structure.

14. A phase change memory device, comprising a plurality of memory cells,
wherein at least one of the plurality of memory cells comprises the integrated circuit of claim 1, and
wherein the phase change memory device is configured to perform an inference mode of an analog artificial intelligence (AI) model, and wherein, in the inference mode, memory elements of the plurality of memory cells are programmed to have a plurality of resistance states corresponding to respective weights of the plurality of memory cells, the plurality of resistance states corresponding to non-overlapping ranges of resistance values.

15. An integrated circuit, comprising:
a first electrode;
a second electrode; and
a body of a phase change material coupled between the first electrode and the second electrode,
wherein the phase change material comprises SiₓSb_{y}Te_{z} doped with SiC, where x, y, z represent respective atomic ratios for compositions Si, Sb, Te.

16. The integrated circuit of claim 15, wherein a bulk stoichiometry of the body of the phase change material comprises:
a Si atomic concentration within a range from about 7% to about 12%,
a Sb atomic concentration within a range from about 27% to about 42%,
a Te atomic concentration within a range from about 40% to about 60%, and
a C atomic concentration within a range from about 10% to about 16%.

17. The integrated circuit of claim 15, wherein a reset drift coefficient of the integrated circuit at an elevated temperature is no more than 0.04.

18. The integrated circuit of claim 15, wherein the body of the phase change material is programmable to a plurality of resistance states including a full reset state and a full set state, and
wherein a change of a conductance of each of the plurality of resistance states is no more than 10% over 1 day.

19. A phase change memory device, comprising a plurality of memory cells, wherein at least one of the plurality of memory cells comprises the integrated circuit of claim 15,
wherein the phase change memory device is configured to perform an inference mode of an analog artificial intelligence (AI) model, and
wherein, in the inference mode, memory elements of the plurality of memory cells are programmed to have a plurality of resistance states corresponding to respective weights of the plurality of memory cells, the plurality of resistance states corresponding to non-overlapping ranges of resistance values.

20. A phase change memory device, comprising:
a plurality of memory cells, wherein each of the plurality of memory cells comprises a memory element comprising:
a first electrode and a second electrode; and
a body of a phase change material coupled between the first electrode and the second electrode, wherein the phase change material comprises SiₓSb_{y}Te_{z}, where x, y, z represent respective atomic ratios for compositions Si, Sb, Te, and wherein a bulk stoichiometry of the body of the phase change material comprises a Si atomic concentration within a range from about 7% to about 12%, a Sb atomic concentration within a range from about 27% to about 42%, and a Te atomic concentration within a range from about 40% to about 60%; and
control circuitry coupled to the plurality of memory cells and configured to control one or more operations on the plurality of memory cells,
wherein the phase change material comprises SiC doped in SiₓSb_{y}Te_{z}, and the bulk stoichiometry of the body of the phase change material comprises: a C atomic concentration within a range from about 10% to about 16%, and
wherein the phase change memory device is configured to perform an inference mode of an analog artificial intelligence (AI) model, and wherein, in the inference mode, memory elements of the plurality of memory cells are programmed to have a plurality of resistance states corresponding to respective weights of the plurality of memory cells, the plurality of resistance states corresponding to non-overlapping ranges of resistance values.
